(19) United States
(12) Patent Application Publication
(10) Pub. No.: US 2024/0377753 A1
(43) Pub. Date: Nov. 14, 2024

(54) DYNAMIC FREEFORM OPTICS FOR LITHOGRAPHY ILLUMINATION BEAM SHAPING

(71) Applicant: KLA Corporation, Milpitas, CA (US)

(72) Inventor: Mahsa Farsad, Sunnyvale, CA (US)

(21) Appl. No.: 18/652,438

(22) Filed: May 1, 2024

Related U.S. Application Data
(60) Provisional application No. 63/464,632, filed on May 8, 2023.

(51) Int. Cl. G03F 7/00

(52) U.S. Cl. CPC G03F 7/70183; G03F 7/70033; G03F 7/70141; G03F 7/702

(57) ABSTRACT

The system includes a light source configured to emit light and a pair of optical elements disposed in the path of the light and are reflective or refractive. The pair of optical elements are spaced apart in parallel planes and have cooperating non-planar surfaces that are configured to produce a first beam shape of the light emitted by the light source, which is directed onto a sample. The pair of optical elements are configured to move in the parallel planes to a position in which the cooperating non-planar surfaces are configured to produce a second beam shape of the light emitted by the light source that is a different shape from the first beam shape and directed onto the sample.

### CROSS-REFERENCE TO RELATED APPLICATIONS

This application claims priority to the provisional patent application filed May 8, 2023, and assigned U.S. App. No. 63/464,632, the disclosure of which is hereby incorporated by reference.

### FIELD OF THE DISCLOSURE

This disclosure relates to semiconductor manufacturing and, more particularly, to illumination systems for lithography processes.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it determines the return-on-investment for a semiconductor manufacturer.

Fabricating semiconductor devices, such as logic and memory devices, typically includes processing a semiconductor workpiece (e.g., wafer, substrate, display panel, etc.) using a large number of fabrication processes to form various features and multiple levels of the semiconductor devices. For example, lithography is a semiconductor fabrication process that involves transferring a pattern from a reticle to a photoresist arranged on a semiconductor workpiece. Additional examples of semiconductor fabrication processes include, but are not limited to, chemical-mechanical polishing (CMP), etch, deposition, and ion implantation. Multiple semiconductor devices may be fabricated in an arrangement on a single semiconductor workpiece that are separated into individual semiconductor devices.

In a lithography process, an illumination system directs light (such as, for example, Deep Ultraviolet (DUV) light, Extreme Ultraviolet (EUV) light, or the like) on to a semiconductor workpiece to expose photoresist to the light. In some instances, it may be desirable to only expose the photoresist to a portion of the light. For example, changing the pupil shape of the beam of light can change which portions of the light are directed onto the semiconductor workpiece. Hard apertures placed in the pupil plane can be used to create customized beam shapes, but these can result in light loss due to intentional vignetting, and each dedicated hard aperture needs to be changed within the illumination system to change the beam shape. Alternatively, multi-element faceted arrays can be used to augment the beam shape, but cost and complexity limit the number of mirrors in the array, which limits that accuracy of shapes that can be produced.

Therefore, what is needed is an illumination system that can dynamically produce different beam shapes.

### BRIEF SUMMARY OF THE DISCLOSURE

An embodiment of the present disclosure provides a system comprising: a light source, an imaging mirror, and a pair of reflective optical elements. The light source may be configured to emit light, and the light emitted by the light source may be deep ultraviolet (DUV) light or extreme ultraviolet (EUV) light. The imaging mirror may be disposed in a light path of the light emitted by the light source, and the imaging mirror may be configured to reflect the light emitted by the light source onto a sample. The pair of reflective optical elements may be disposed in the light path between the light source and the imaging mirror, and the pair of reflective optical elements may be spaced apart in parallel planes and have cooperating non-planar surfaces. The light emitted by the light source may be reflected between the cooperating non-planar surfaces to produce a first beam shape of the light to be reflected on the sample by the imaging mirror. At least one of the pair of reflective optical elements may be movable within one of the parallel planes to a position in which the light emitted by the light source reflected between the cooperating non-planar surfaces produces a second beam shape that is a different shape from the first beam shape.

In some embodiments, the system may further comprise a collimator disposed in the light path between the light source and the pair of reflective optical elements. The collimator may be configured to direct the light emitted by the light source to be reflected between the cooperating non-planar surfaces of the pair of reflective optical elements.

In some embodiments, the system may further comprise a pupil disposed in the light path between the pair of reflective optical elements and the imaging mirror. The light in the first beam shape or the second beam shape may be directed through the pupil to the imaging mirror.

In some embodiments, the cooperating non-planar surfaces of the pair of reflective optical elements may form a rectangular prism.

In some embodiments, the system may further comprise a first actuator. The first actuator may be configured to move a first reflective optical element of the pair of reflective optical elements in a first direction within a first plane of the pair of parallel planes to the position in which the light emitted by the light source reflected between the cooperating non-planar surfaces produces the second beam shape.

In some embodiments, the system may further comprise a second actuator. The second actuator may be configured to move a second reflective optical element of the pair of reflective optical elements in a second direction within a second plane of the parallel planes to the position in which the light emitted by the light source reflected between the cooperating non-planar surfaces produces the second beam shape. The second direction may be opposite to the first direction.

In some embodiments, the first beam shape and the second beam shape may be different shapes selected from a group comprising: a circular shape, an annular shape, a dipole shape, a quasar shape, slit shape, and pinhole shape.

Another embodiment of the present disclosure provides a system comprising: a light source, an imaging mirror, and a pair of refractive optical elements. The light source may be configured to emit light, and the light emitted by the light source is deep ultraviolet (DUV) light or extreme ultraviolet (EUV) light. The imaging mirror may be disposed in a light path of the light emitted by the light source, and the imaging mirror may be configured to reflect the light emitted by the light source onto a sample. The pair of refractive optical elements may be disposed in the light path between the light source and the imaging mirror, and the pair of refractive optical elements may be spaced apart in parallel planes and have cooperating non-planar surfaces. The light emitted by the light source may be refracted through the cooperating non-planar surfaces to produce a first beam shape of the light to be reflected on the sample by the imaging mirror. At least one of the pair of refractive optical elements may be movable within one of the parallel planes to a position in which the light emitted by the light source refracted through the cooperating non-planar surfaces produces a second beam shape that is a different shape from the first beam shape.

In some embodiments, the system may further comprise a collimator disposed in the light path between the light source and the pair of refractive optical elements. The collimator may be configured to direct the light emitted by the light source to be refracted through the cooperating non-planar surfaces of the pair of refractive optical elements.

In some embodiments, the system may further comprise a pupil disposed in the light path between the pair of refractive optical elements and the imaging mirror. The light in the first beam shape or the second beam shape may be directed through the pupil to the imaging mirror.

In some embodiments, the cooperating non-planar surfaces of the pair of refractive optical elements may form a rectangular prism.

In some embodiments, the system may further comprise a first actuator. The first actuator may be configured to move a first refractive optical element of the pair of refractive optical elements in a first direction within a first plane of the pair of parallel planes to the position in which the light emitted by the light source refracted through the cooperating non-planar surfaces produces the second beam shape.

In some embodiments, the system may further comprise a second actuator. The second actuator may be configured to move a second refractive optical element of the pair of refractive optical elements in a second direction within a second plane of the parallel planes to the position in which the light emitted by the light source refracted through the cooperating non-planar surfaces produces the second beam shape. The second direction may be opposite to the first direction.

In some embodiments, the first beam shape and the second beam shape may be different shapes selected from a group comprising: a circular shape, an annular shape, a dipole shape, a quasar shape, slit shape, and pinhole shape.

Another embodiment of the present disclosure provides a method. The method may comprise emitting light from a light source. The light emitted by the light source may be deep ultraviolet (DUV) light or extreme ultraviolet (EUV) light. The method may further comprise transmitting the light through a pair of optical elements. The pair of optical elements may be spaced apart in parallel planes and may have cooperating non-planar surfaces that are configured to produce a first beam shape of the light emitted by the light source. The method may further comprise directing the light in the first beam shape onto a sample. The method may further comprise moving the pair of optical elements in the parallel planes to a position in which the cooperating non-planar surfaces are configured to produce a second beam shape of the light emitted by the light source that is a different shape from the first beam shape. The method may further comprise directing the light in the second beam shape onto the sample.

In some embodiments, before transmitting the light through the pair of optical elements, the method may further comprise collimating the light with a collimator to direct the light emitted by the light source to be transmitted through the pair of optical elements.

In some embodiments, the pair of optical elements may comprise a pair of reflective optical elements, and transmitting the light through the pair of optical elements may comprise reflecting the light emitted by the light source between the cooperating non-planar surfaces to produce the first beam shape of the light.

In some embodiments, the pair of optical elements may comprise a pair of refractive optical elements, and transmitting the light through the pair of optical elements may comprise refracting the light emitted by the light source through the cooperating non-planar surfaces to produce the first beam shape of the light.

In some embodiments, moving the pair of optical elements in the parallel planes to the position in which the cooperating non-planar surfaces are configured to produce the second beam shape may comprise moving, with a first actuator, a first optical element of the pair of optical elements in a first direction within a first plane of the parallel planes to the position to produce the second beam shape.

In some embodiments, moving the pair of optical elements in the parallel planes to the position in which the cooperating non-planar surfaces are configured to produce the second beam shape may further comprise moving, with a second actuator, a second optical element of the pair of optical elements in a second direction within a second plane of the parallel planes to the position to produce the second beam shape. The second direction may be opposite to the first direction.

### DESCRIPTION OF THE DRAWINGS

For a fuller understanding of the nature and objects of the disclosure, reference should be made to the following detailed description taken in conjunction with the accompanying drawings, in which:

FIG. 1 is a diagram of a system according to an embodiment of the present disclosure;

FIG. 2 is a diagram of a system according to another embodiment of the present disclosure;

FIG. 3A is a diagram of an exemplary pair of reflective optical elements of the present disclosure;

FIG. 3B is a diagram of an exemplary pair of refractive optical elements of the present disclosure;

FIGS. 4A to 4F illustrate exemplary beam shapes produced by systems of the present disclosure;

FIG. 5 is a flowchart of a method according to an embodiment of the present disclosure;

FIG. 6 is a flowchart of a method according to another embodiment of the present disclosure;

FIG. 7 is a flowchart of a method according to another embodiment of the present disclosure;

FIG. 8 is a flowchart of a method according to another embodiment of the present disclosure; and

FIG. 9 is a flowchart of a method according to another embodiment of the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

An embodiment of the present disclosure provides a system 100. The system 100 may be part of an illumination system used to produce light for lithography processes in semiconductor manufacturing or inspection of reticles and wafers.

The system 100 may comprise a light source 110. The light source 110 may be configured to emit light 111. The light 111 emitted by the light source 110 may be deep ultraviolet (DUV) light, extreme ultraviolet (EUV) light, or other types of light, depending on the application of the system 100. In some embodiments, the light source 110 may be a DUV plasma source or an EUV plasma source.

The system 100 may further comprise an imaging mirror 120. The imaging mirror 120 may be disposed in a path of the light 111 emitted by the light source 110. The imaging mirror 120 may be configured to reflect the light 111 emitted by the light source 110 onto a sample 101. The sample 101 may be a semiconductor substrate, wafer, workpiece, or the like. The imaging mirror 120 may be a planar mirror, concave mirror, convex mirror, or other shapes. In some embodiments, the system 100 may include a combination of optical elements (reflective and/or refractive) in addition to the imaging mirror 120 that are configured to reflect the light 111 emitted by the light source 110 onto the sample 101. The sample 101 may be disposed on a stage 105. The stage 105 may be movable by one or more actuators in one or more directions (e.g., in-plane (e.g., x and y directions) and/or out-of-plane (e.g., z direction) to adjust the position of the sample 101 to change where the light 111 emitted by the light source 110 is reflected onto the sample 101.

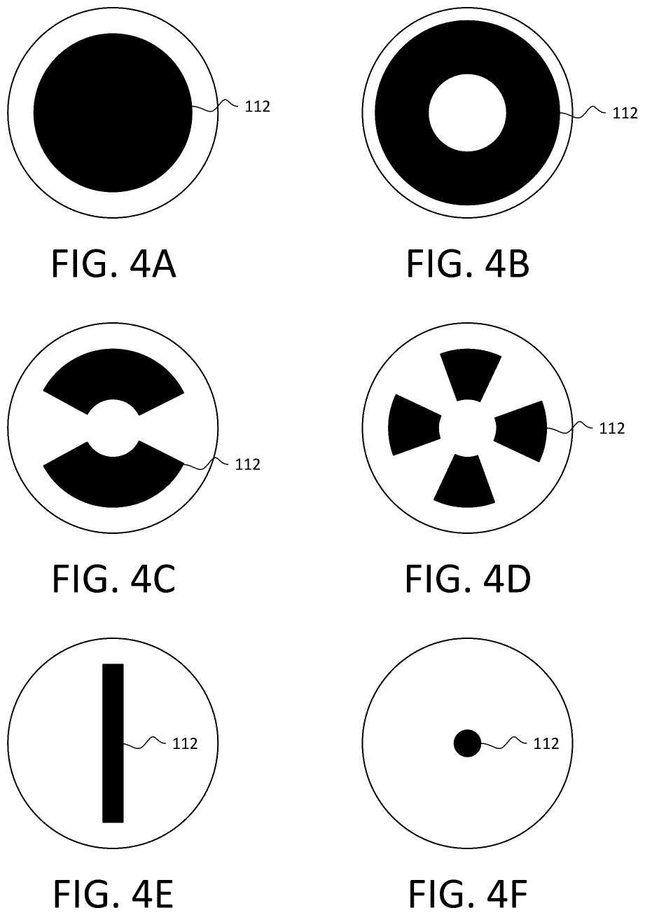

The system 100 may further comprise a pair of optical elements disposed in the path of the light 111 emitted by the light source 110 between the light source 110 and the imaging mirror 120. The pair of optical elements may be spaced apart in parallel planes and have cooperating non-planar surfaces that are configured to produce a first beam shape of the light 111 emitted by the light source 110. At least one of the pair of optical elements may be movable within one of the parallel planes to a position in which the cooperating non-planar surfaces are configured to produce a second beam shape of the light 111 emitted by the light source 110 that is different from the first beam shape. For example, FIGS. 4A to 4F illustrate different exemplary beam shapes of the light 112 reflected onto the sample 101, in which the first beam shape and the second beam shape are independently chosen from a circular shape (shown in FIG. 4A), an annular shape (as shown in FIG. 4B), a dipole shape (as shown in FIG. 4C), a quasar shape (as shown in FIG. 4D), a slit shape (as shown in FIG. 4E), a pinhole shape (as shown in FIG. 4F), or other shapes, and is not limited herein. In FIGS. 4A to 4F, the dark shaded portions of the shapes may correspond to the light 112 to be reflected onto the sample 101 (i.e., the unshaded portions of the shapes may correspond to areas without light). Alternatively, in some or all of FIGS. 4A to 4F, the dark shaded portions of the shapes may correspond to areas without light, while the unshaded portions of the shapes within the circle may correspond to the light 112 to be reflected onto the sample 101.

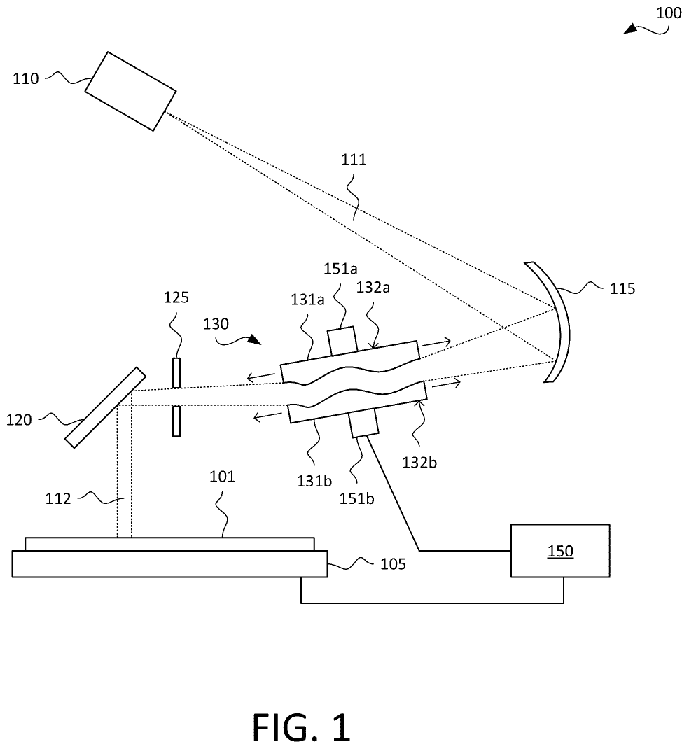

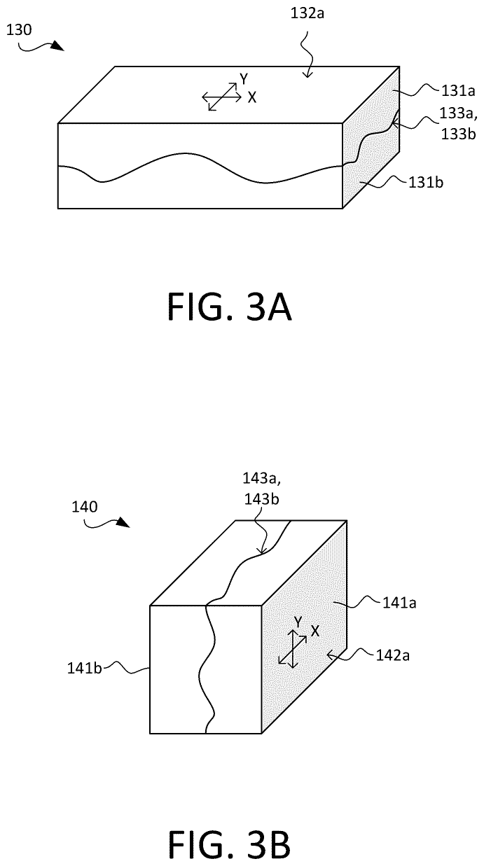

In some embodiments, the pair of optical elements may comprise a pair of reflective optical elements 130, as shown in FIG. 1. The pair of reflective optical elements 130 may comprise a first reflective optical element 131a and a second reflective optical element 131b. The first reflective optical element 131a may be disposed in a first plane 132a and the second reflective optical element 131b may be disposed in a second plane 132b, such that the first reflective optical element 131a and the second reflective optical element 131b are spaced apart in the parallel planes of the first plane 132a and the second plane 132b. For example, the first reflective optical element 131a and the second reflective optical element 131b may be spaced apart by a distance of several millimeters to tens of millimeters. The pair of reflective optical elements 130 may have cooperating non-planar surfaces. For example, the first reflective optical element 131a may have a first non-planar reflective surface 133a, and the second reflective optical element 131b may have a second non-planar reflective surface 133b. As shown in FIG. 3A, the first non-planar reflective surface 133a and the second non-planar reflective surface 133b may cooperate to form a rectangular prism. In some embodiments, the pair of reflective optical elements 130 may form non-rectangular, irregular, or other shapes if the first non-planar reflective surface 133a and the second non-planar reflective surface 133b were joined together and is not limited by the rectangular prism shown in FIG. 3A. The light 111 emitted by the light source 110 may be reflected between the cooperating non-planar surfaces to produce a first beam shape of the light 112 to be reflected on the sample 101 by the imaging mirror 120. In some embodiments, the first reflective optical element 131a and the second reflective optical element 131b may be made of glass or other reflective materials. In some embodiments, the first non-planar reflective surface 133a and the second non-planar reflective surface 133b may include a reflective coating. At least one of the first reflective optical element 131a and the second reflective optical element 131b may be movable within a respective one of the first plane 132a and the second plane 132b to a position in which the light 111 emitted by the light source 110 reflected between the cooperating non-planar surfaces produces a second beam shape of the light 112 to be reflected on the sample 101 by the imaging mirror 120 that is different from the first beam shape. Based on the profile of the first non-planar reflective surface 133a and the second non-planar reflective surface 133b, the light 111 reflects between the pair of reflective optical elements 130 to produce the first beam shape of the light 112. By moving at least one of the pair of reflective optical elements 130, the path of the light 111 that reflects between the pair of reflective optical elements 130 may change, thereby producing the second beam shape of the light 112.

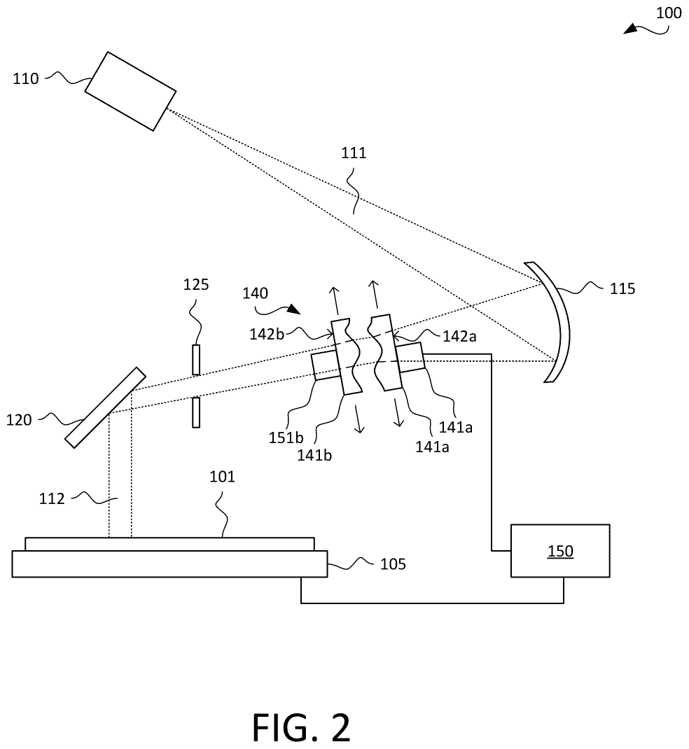

In some embodiments, the pair of optical elements may comprise a pair of refractive optical elements 140, as shown in FIG. 2. The pair of refractive optical elements 140 may comprise a first refractive optical element 141a and a second refractive optical element 141b. The first refractive optical element 141a may be disposed in a first plane 142a and the second refractive optical element 141b may be disposed in a second plane 142b, such that the first refractive optical element 141a and the second refractive optical element 141b are spaced apart in the parallel planes of the first plane 142a and the second plane 142b. For example, the first refractive optical element 141a and the second refractive optical element 141b may be spaced apart by a distance of several millimeters to tens of millimeters. The pair of refractive optical elements 140 may have cooperating non-planar surfaces. For example, the first refractive optical element 141a may have a first non-planar refractive surface 143a, and the second refractive optical element 141b may have a second non-planar refractive surface 143b. As shown in FIG. 3B, the first non-planar refractive surface 143a and the second non-planar refractive surface 143b may cooperate to form a rectangular prism. In some embodiments, the pair of refractive optical elements 140 may form non-rectangular, irregular, or other shapes if the first non-planar refractive surface 143a and the second non-planar refractive surface 143b were joined together and is not limited by the rectangular prism shown in FIG. 3B. The light 111 emitted by the light source 110 may be refracted through the cooperating non-planar surfaces to produce a first beam shape of the light 112 to be reflected on the sample 101 by the imaging mirror 120. In some embodiments, the first refractive optical element 141a and the second refractive optical element 141b may be made of optical glass such as BK7 or fused silica. In some embodiments, the first refractive optical element 141a and the second refractive optical element 141b may have a thickness of a few millimeters to hundreds of millimeters, depending on the diameter/width of the elements. At least one of the first refractive optical element 141a and the second refractive optical element 141b may be movable within a respective one of the first plane 142a and the second plane 142b to a position in which the light 111 emitted by the light source 110 refracted through the cooperating non-planar surfaces produces a second beam shape of the light 112 to be reflected on the sample 101 by the imaging mirror 120 that is different from the first beam shape. Based on the profile of the first non-planar refractive surface 143a and the second non-planar refractive surface 143b, the light 111 reflects between the pair of refractive optical elements 140 to produce the first beam shape of the light 112. By moving at least one of the pair of refractive optical elements 140, the path of the light 111 that reflects between the pair of refractive optical elements 140 may change, thereby producing the second beam shape of the light 112.

Cooperation between two surfaces of the pair of reflective optical elements 130 and the pair of refractive optical elements 140 can create a beam shape that may be equivalent to a single surface with a different profile. By shifting the two cooperating surfaces with respect to each other, several different beam shapes can be produced. For example, five or more different beam shapes can be produced with only two surfaces by shifting them relative to each other in the x and y directions. In comparison, conventional systems may rely on five different sets of optics to produce the same five beam shapes.

The system 100 may further comprise a processor 150. The processor 150 may include a microprocessor, a microcontroller, or other devices. The processor 150 may be coupled to the components of the system 100 in any suitable manner (e.g., via one or more transmission media, which may include wired and/or wireless transmission media) such that the processor 150 can receive output. The processor 150 may be configured to perform a number of functions using the output. An inspection tool can receive instructions or other information from the processor 150. The processor 150 optionally may be in electronic communication with another inspection tool, a metrology tool, a repair tool, or a review tool (not illustrated) to receive additional information or send instructions.

The processor 150 may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The processor 150 may be disposed in or otherwise part of the system 100 or another device. In an example, the processor 150 and may be part of a standalone control unit or in a centralized quality control unit. Multiple processors 150 may be used, defining multiple subsystems of the system 100.

The processor 150 may be implemented in practice by any combination of hardware, software, and firmware. Also, its functions as described herein may be performed by one unit, or divided up among different components, each of which may be implemented in turn by any combination of hardware, software and firmware. Program code or instructions for the processor 150 to implement various methods and functions may be stored in readable storage media, such as a memory.

If the system 100 includes more than one subsystem, then the different processors 150 may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor 150 may be configured to perform a number of functions using the output of the system 100 or other output. For instance, the processor 150 may be configured to send the output to an electronic data storage unit or another storage medium. The processor 150 may be further configured as described herein.

The processor 150 may be configured according to any of the embodiments described herein. The processor 150 also may be configured to perform other functions or additional steps using the output of the system 100 or using images or data from other sources.

The processor 150 may be communicatively coupled to any of the various components or sub-systems of system 100 in any manner known in the art. Moreover, the processor 150 may be configured to receive and/or acquire data or information from other systems (e.g., inspection results from an inspection system such as a review tool, a remote database including design data and the like) by a transmission medium that may include wired and/or wireless portions. In this manner, the transmission medium may serve as a data link between the processor 150 and other subsystems of the system 100 or systems external to system 100. Various steps, functions, and/or operations of system 100 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random-access memory, a magnetic or optical disk, a non-volatile memory, a solid-state memory, a magnetic tape, and the like. A carrier medium may include a transmission medium such as a wire, cable, or wireless transmission link. For instance, the various steps described throughout the present disclosure may be carried out by a single processor 150 (or computer subsystem) or, alternatively, multiple processors 150 (or multiple computer subsystems). Moreover, different sub-systems of the system 100 may include one or more computing or logic systems. Therefore, the above description should not be interpreted as a limitation on the present disclosure but merely an illustration.

The processor 150 may be in electronic communication with the light source 110. For example, the processor 150 may be configured to send instructions to the light source 110 to emit light 111 to be transmitted through the pair of optical elements.

The processor 150 may be in electronic communication with the stage 105. For example, the processor 150 may be configured to send instructions to a motor or actuators of the stage 105 to cause the stage to translate or rotate, which caused the light 112 reflected onto the sample 101 to scan across the sample 101 or change which portion of the sample 101 is illuminated by the light 112.

The processor 150 may be in electronic communication with one or more actuators configured to control the positions of the pair of optical elements. For example, the system 100 may further comprise a first actuator 151a configured to move a first optical element within the first plane of the parallel planes and a second actuator 151b configured to move a second optical element within the second plane of the parallel planes. In an instance, the first actuator 151a may be configured to move the first reflective optical element 131a within the first plane 132a, and the second actuator 151b may be configured to move the second reflective optical element 131b within the second plane 132b, as shown in FIG. 1. The first actuator 151a and the second actuator 151b may be configured to move the pair of reflective optical elements 130 in the X direction or the Y direction of the respective planes, as shown in FIG. 3A. In another instance, the first actuator 151a may be configured to move the first refractive optical element 141a within the first plane 142a, and the second actuator 151b may be configured to move the second refractive optical element 141b within the second plane 142b, as shown in FIG. 2. The first actuator 151a and the second actuator 151b may be configured to move the pair of refractive optical elements 140 in the X direction or the Y direction of the respective planes, as shown in FIG. 3B.

In an instance, the processor 150 may be configured to send instructions to move only one optical element of the pair of optical elements relative to the other to produce the second beam shape of the light 112 reflected onto the sample 101. For example, the first actuator 151a may be configured to move the respective one of the first reflective optical element 131a or the first refractive optical element 141a, while the second reflective optical element 131b or the second refractive optical element 141b remains stationary. Alternatively, the second actuator 151b may be configured to move the respective one of the second reflective optical element 131b or the second refractive optical element 141b, while the first reflective optical element 131a of the first refractive optical element 141a remains stationary. Thus, the linear position of pair of optical elements may define whether the first beam shape, the second beam shape, or other beam shapes are produced, as controlled by the first actuator 151a or the second actuator 151b.

In another instance, the processor 150 may be configured to send instructions to move both optical elements of the pair of optical elements to produce the second beam shape of the light 112 reflected onto the sample 101. For example, the first actuator 151a may be configured to move the respective one of the first reflective optical element 131a or the first refractive optical element 141a, and the second actuator 151b may be configured to move the respective one of the second reflective optical element 131b or the second refractive optical element 141b. Each optical element may be moved in different directions and/or along different axes. For example, both the first actuator 151a and the second actuator 151b may be configured to move a respective optical element along the X-axis in their respective planes. Thus, the pair of optical elements can be moved in opposite directions to positions which define whether the first beam shape, the second beam shape, or other beam shapes are produced, as controlled by the first actuator 151a and the second actuator 151b, with less relative movement and movement time compared to using only one actuator. Alternatively, the first actuator 151a may be configured to move a first optical element along the X-axis in the first plane, and the second actuator 151b may be configured to move a second optical element along the Y-axis in the second plane. Thus, the two-dimensional positions of the pair of optical elements may define whether the first beam shape, the second beam shape, or other beam shapes are produced, as controlled by the first actuator 151a and the second actuator 151b.

In some embodiments, the system 100 may comprise additional actuators configured to move each optical element of the pair of optical elements in additional directions. For example, each of the first reflective optical element 131a and the second reflective optical element 131b or each of the first refractive optical element 141a and the second refractive optical element 141b may be configured to move in both the X-direction and the Y-direction in their respective planes with one or more actuators, for further positional control.

In some embodiments, the system 100 may further comprise a collimator 115. The collimator 115 may be disposed in the path of the light 111 emitted by the light source 110 between the light source 110 and the pair of optical elements. The collimator 115 may be configured to direct the light 111 to be transmitted through the pair of optical elements. For example, the collimator 115 may be configured to direct the light 111 to be reflected between the pair of reflective optical elements 130. Alternatively, the collimator 115 may be configured to direct the light 111 to be refracted through the pair of refractive optical elements 140. By using the collimator 115, less light 111 may be lost as it is transmitted through the pair of optical elements and is used to form the first beam shape and the second beam shape of the light 112 to be reflected onto the sample 101.

In some embodiments, the system 100 may further comprise a pupil 125. The pupil 125 may be disposed in the path of the light 112 to be reflected onto the sample 101 between the pair of optical elements and the imaging mirror 120. The light 112 in the first beam shape or the second beam shape may be directed through the pupil 125 to the imaging mirror 120 to be reflected onto the sample.

In some embodiments, the collimator 115 and the imaging mirror 120 can be replaced with any type of optical components composed of a single reflective, single refractive, or multiple elements with reflective and/or refractive surfaces. In some embodiments, the pair of reflective optical elements 130 or the pair of refractive optical elements 140 may not be disposed between the collimator and the imaging mirror 120 and may instead by disposed between other elements of the system 100.

With the system 100, different beam shapes can be produced by transmitting the light 111 through a pair of optical elements, and the beam shape of the light 112 reflected onto a sample 101 can be dynamically changed by moving one of the optical elements relative to the other, which improves efficiency and accuracy compared to prior beam shaping methods.

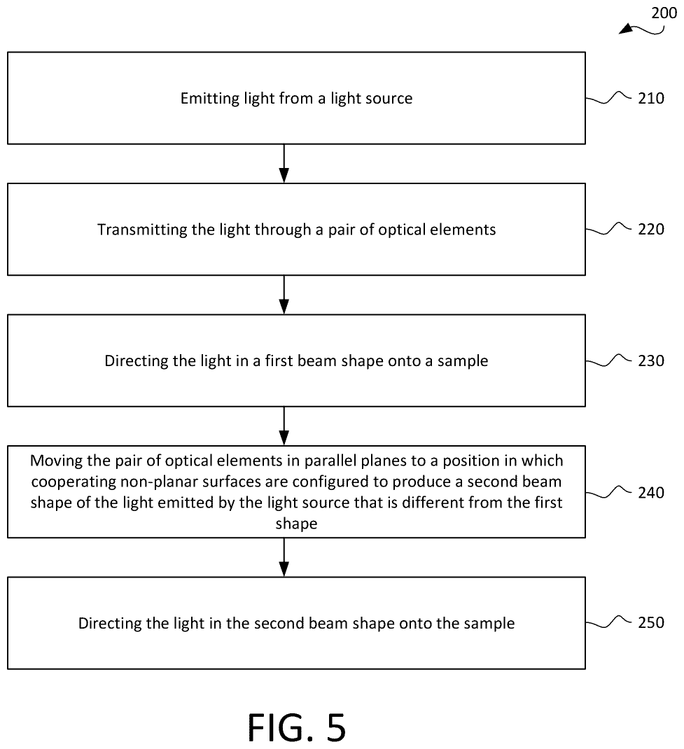

Another embodiment of the present disclosure provides a method 200. As shown in FIG. 5, the method 200 may comprise the following steps.

At step 210, light is emitted from a light source. The light emitted by the light source may be deep ultraviolet (DUV) light or extreme ultraviolet (EUV) light.

At step 220, the light is transmitted through a pair of optical elements. The pair of optical elements may be spaced apart in parallel planes and may have cooperating non-planar surfaces that may be configured to produce a first beam shape of the light emitted by the light source.

At step 230, the light in the first beam shape is directed onto a sample. The sample may be a semiconductor substrate, wafer, workpiece, or the like. The light may be directed by one or more optical components, such as an imaging mirror. The one or more optical components may be reflective and/or refractive in order to direct the light onto the sample. The light may be configured to cure a photoresist disposed on the sample according to the first beam shape.

At step 240, the pair of optical elements are moved in the parallel planes to a position in which the cooperating non-planar surfaces are configured to produce a second beam shape of the light emitted by the light source. The second beam shape may be a different shape from the first beam shape.

At step 250, the light in the second beam shape is directed onto the sample. The same arrangement of the one or more optical components used to direct the light in the first beam shape onto the sample in step 230 may be used to direct the light in the second beam shape onto the sample in step 250.

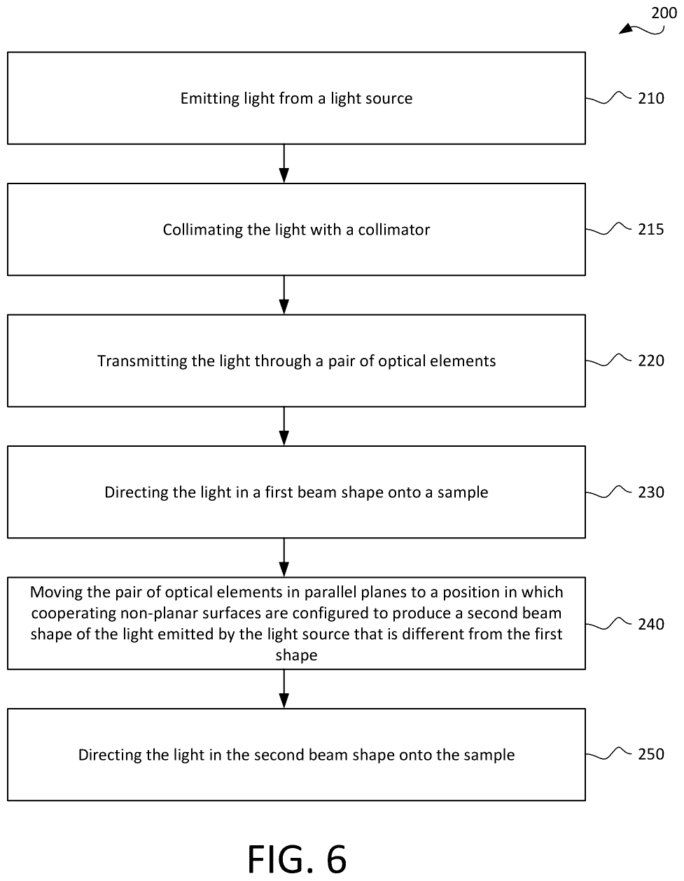

In some embodiments, the method 200 may further comprise step 215, as shown in FIG. 6. At step 215, the light emitted by the light source is collimated with a collimator to direct the light to be transmitted through the pair of optical elements. Step 215 may be performed between step 210 and step 220, as shown in FIG. 6. By collimating the light, less light may be lost as it is transmitted through the pair of optical elements and is used to form the first beam shape and the second beam shape of the light to be directed onto the sample.

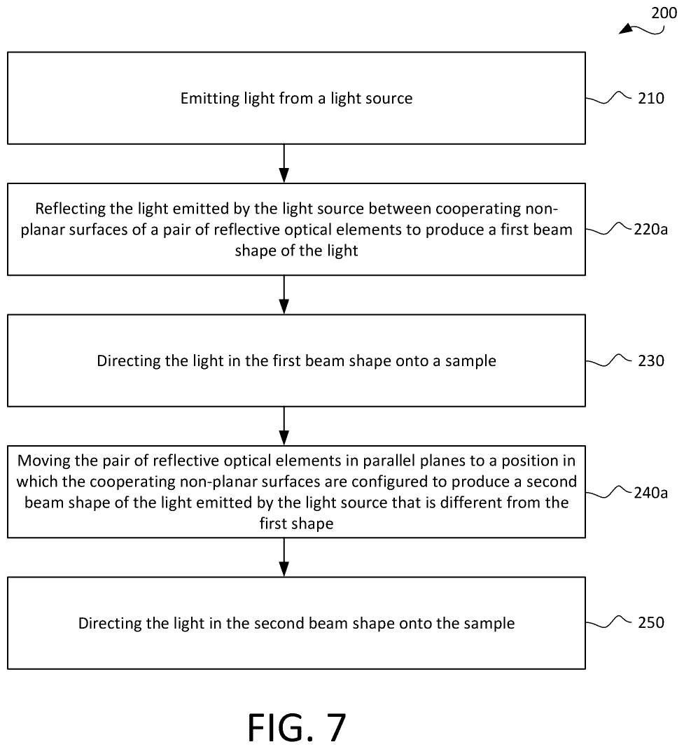

In some embodiments, the pair of optical elements may comprise a pair of reflective optical elements. Accordingly, step 220 and step 240 of the method 200 may be replaced with step 220a and step 240a, as shown in FIG. 7. At step 220a, the light emitted by the light source is reflected between the cooperating non-planar surfaces of the pair of reflective optical elements to produce the first beam shape of the light. At step 240a, the pair of reflective optical elements are moved in the parallel planes to a position in which the cooperating non-planar surfaces are configured to produce a second beam shape of the light emitted by the light source that is different from the first beam shape. Based on the profile of the cooperating non-planar surfaces, the light reflects between the pair of reflective optical elements to produce the first beam shape of the light. By moving at least one of the pair of reflective optical elements, the path of the light that reflects between the pair of reflective optical elements may change, thereby producing the second beam shape of the light.

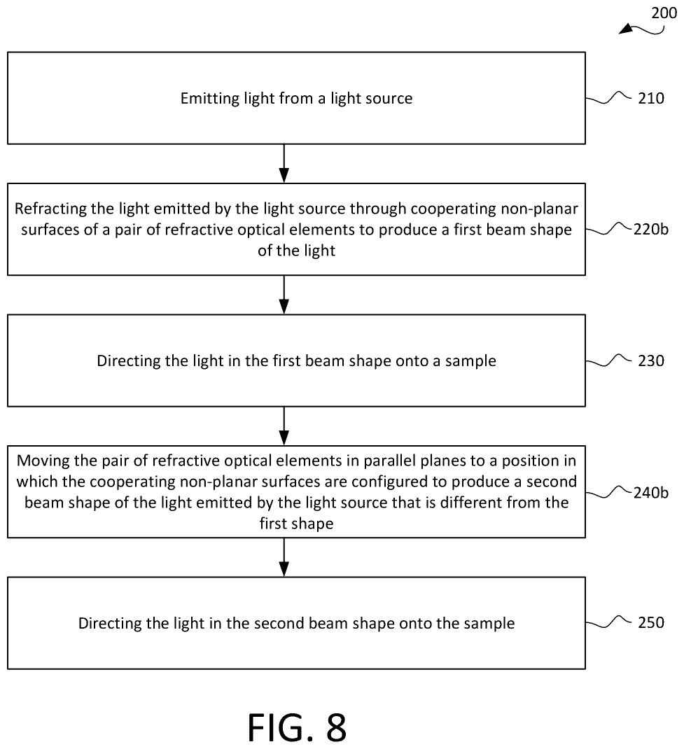

In some embodiments, the pair of optical elements may comprise a pair of refractive optical elements. Accordingly, step 220 and step 240 of the method 200 may be replaced with step 220b and step 240b, as shown in FIG. 8. At step 220b, the light emitted by the light source is refracted through the cooperating non-planar surfaces of the pair of refractive optical elements to produce the first beam shape of the light. At step 240b, the pair of refractive optical elements are moved in the parallel planes to a position in which the cooperating non-planar surfaces are configured to produce a second beam shape that is different from the first beam shape. Based on the profile of the cooperating non-planar surfaces, the light refracts through the pair of refractive optical elements to produce the first beam shape of the light. By moving at least one of the pair or refractive optical elements, the path of the light that is refracted through the pair of refractive optical elements may change, thereby producing the second beam shape of the light.

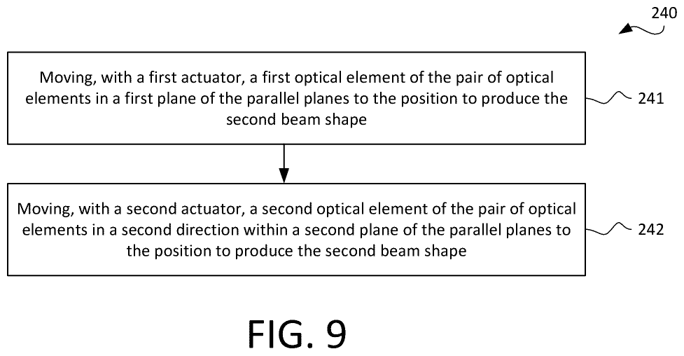

In some embodiments, step 240 may comprise at least one of the following steps, as shown in FIG. 9.

At step 241, a first optical element of the pair of optical elements is moved in a first plane of the parallel planes with a first actuator to the position to produce the second beam shape.

At step 242, a second optical element of the pair of optical elements is moved in a second plane of the parallel planes with a second actuator to the position to produce the second beam shape.

In an instance, step 240 may comprise one of step 241 or step 242. In other words, only one optical element of the pair of optical elements may be moved relative to the other to produce the second beam shape. Thus, the linear position of pair of optical elements may define whether the first beam shape, the second beam shape, or other beam shapes are produced, as controlled by the first actuator or the second actuator.

In another instance, step 240 may comprise both step 241 and step 242. In other words, each optical element of the pair of optical elements may be moved relative to the other to produce the second beam shape. Each optical element may be moved in different directions and/or along different axes. For example, the first actuator may be configured to move the first optical element along an X-axis in the first plane, and the second actuator may be configured to move the second optical element along an X-axis in the second plane. Thus, the pair of optical elements can be moved in opposite directions to positions which define whether the first beam shape, the second beam shape, or other beam shapes are produced, as controlled by the first actuator and the second actuator, with less relative movement and movement time compared to using only one actuator. Alternatively, the first actuator may be configured to move the first optical element along an X-axis in the first plane, and the second actuator may be configured to move the second optical element along a Y-axis in the second plane. Thus, the two-dimensional positions of the pair of optical elements may define whether the first beam shape, the second beam shape, or other beam shapes are produced, as controlled by the first actuator and the second actuator.

With the method 200, different beam shapes can be produced by transmitting light through a pair of optical elements, and the beam shape of the light reflected onto a sample can be dynamically changed by moving one of the optical elements relative to the other, which improves efficiency and accuracy compared to prior beam shaping methods.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
a light source configured to emit light, wherein the light emitted by the light source is deep ultraviolet (DUV) light or extreme ultraviolet (EUV) light;
an imaging mirror disposed in a light path of the light emitted by the light source, wherein the imaging mirror is configured to reflect the light emitted by the light source onto a sample; and
a pair of reflective optical elements disposed in the light path between the light source and the imaging mirror, wherein the pair of reflective optical elements are spaced apart in parallel planes and have cooperating non-planar surfaces, and the light emitted by the light source is reflected between the cooperating non-planar surfaces to produce a first beam shape of the light to be reflected on the sample by the imaging mirror;
wherein at least one of the pair of reflective optical elements is movable within one of the parallel planes to a position in which the light emitted by the light source reflected between the cooperating non-planar surfaces produces a second beam shape that is a different shape from the first beam shape.

2. The system of claim 1, further comprising a collimator disposed in the light path between the light source and the pair of reflective optical elements, wherein the collimator is configured to direct the light emitted by the light source to be reflected between the cooperating non-planar surfaces of the pair of reflective optical elements.

3. The system of claim 1, further comprising a pupil disposed in the light path between the pair of reflective optical elements and the imaging mirror, wherein the light in the first beam shape or the second beam shape is directed through the pupil to the imaging mirror.

4. The system of claim 1, wherein the cooperating non-planar surfaces of the pair of reflective optical elements form a rectangular prism.

5. The system of claim 1, further comprising a first actuator configured to move a first reflective optical element of the pair of reflective optical elements in a first direction within a first plane of the pair of parallel planes to the position in which the light emitted by the light source reflected between the cooperating non-planar surfaces produces the second beam shape.

6. The system of claim 5, further comprising a second actuator configured to move a second reflective optical element of the pair of reflective optical elements in a second direction within a second plane of the parallel planes to the position in which the light emitted by the light source reflected between the cooperating non-planar surfaces produces the second beam shape, wherein the second direction is opposite to the first direction.

7. The system of claim 1, wherein the first beam shape and the second beam shape are different shapes selected from a group comprising: a circular shape, an annular shape, a dipole shape, a quasar shape, a slit shape, and a pinhole shape.

8. A system comprising:
a light source configured to emit light, wherein the light emitted by the light source is deep ultraviolet (DUV) light or extreme ultraviolet (EUV) light;
an imaging mirror disposed in a light path of the light emitted by the light source, wherein the imaging mirror is configured to reflect the light emitted by the light source onto a sample; and
a pair of refractive optical elements disposed in the light path between the light source and the imaging mirror, wherein the pair of refractive optical elements are spaced apart in parallel planes and have cooperating non-planar surfaces, and the light emitted by the light source is refracted through the cooperating non-planar surfaces to produce a first beam shape of the light to be reflected on the sample by the imaging mirror;
wherein at least one of the pair of refractive optical elements is movable within one of the parallel planes to a position in which the light emitted by the light source refracted through the cooperating non-planar surfaces produces a second beam shape that is a different shape from the first beam shape.

9. The system of claim 8, further comprising a collimator disposed in the light path between the light source and the pair of refractive optical elements, wherein the collimator is configured to direct the light emitted by the light source to be refracted through the cooperating non-planar surfaces of the pair of refractive optical elements.

10. The system of claim 8, further comprising a pupil disposed in the light path between the pair of refractive optical elements and the imaging mirror, wherein the light in the first beam shape or the second beam shape is directed through the pupil to the imaging mirror.

11. The system of claim 8, wherein the cooperating non-planar surfaces of the pair of refractive optical elements form a rectangular prism.

12. The system of claim 8, further comprising a first actuator configured to move a first refractive optical element of the pair of refractive optical elements in a first direction within a first plane of the pair of parallel planes to the position in which the light emitted by the light source refracted through the cooperating non-planar surfaces produces the second beam shape.

13. The system of claim 12, further comprising a second actuator configured to move a second refractive optical element of the pair of refractive optical elements in a second direction within a second plane of the parallel planes to the position in which the light emitted by the light source refracted through the cooperating non-planar surfaces produces the second beam shape, wherein the second direction is opposite to the first direction.

14. The system of claim 8, wherein the first beam shape and the second beam shape are different shapes selected from a group comprising: a circular shape, an annular shape, a dipole shape, a quasar shape, a slit shape, and a pinhole shape.

15. A method comprising:
emitting light from a light source, wherein the light emitted by the light source is deep ultraviolet (DUV) light or extreme ultraviolet (EUV) light;
transmitting the light through a pair of optical elements, wherein the pair of optical elements are spaced apart in parallel planes and have cooperating non-planar surfaces that are configured to produce a first beam shape of the light emitted by the light source;
directing the light in the first beam shape onto a sample;
moving the pair of optical elements in the parallel planes to a position in which the cooperating non-planar surfaces are configured to produce a second beam shape of the light emitted by the light source that is a different shape from the first beam shape; and
directing the light in the second beam shape onto the sample.

16. The method of claim 15, wherein before transmitting the light through the pair of optical elements, the method further comprises:
collimating the light with a collimator to direct the light emitted by the light source to be transmitted through the pair of optical elements.

17. The method of claim 15, wherein the pair of optical elements comprises a pair of reflective optical elements, and transmitting the light through the pair of optical elements comprises:
reflecting the light emitted by the light source between the cooperating non-planar surfaces to produce the first beam shape of the light.

18. The method of claim 15, wherein the pair of optical elements comprises a pair of refractive optical elements, and transmitting the light through the pair of optical elements comprises:
refracting the light emitted by the light source through the cooperating non-planar surfaces to produce the first beam shape of the light.

19. The method of claim 15, wherein moving the pair of optical elements in the parallel planes to the position in which the cooperating non-planar surfaces are configured to produce the second beam shape comprises:
moving, with a first actuator, a first optical element of the pair of optical elements in a first direction within a first plane of the parallel planes to the position to produce the second beam shape.

20. The method of claim 19, wherein moving the pair of optical elements in the parallel planes to the position in which the cooperating non-planar surfaces are configured to produce the second beam shape further comprises:
moving, with a second actuator, a second optical element of the pair of optical elements in a second direction within a second plane of the parallel planes to the position to produce the second beam shape, wherein the second direction is opposite to the first direction.
